(19) United States
(12) Patent Application Publication
(10) Pub. No.: US 2012/0029852 A1
(43) Pub. Date: Feb. 2, 2012

(54) BATTERY MONITOR SYSTEM ATTACHED TO A VEHICLE WIRING HARNESS

(76) Inventors: Lonnie C. Goff, Tempe, AZ (US); Michael Richard Conley, Thousand Oaks, CA (US); Mark Edmond Eidson, Tempe, AZ (US)

(21) Appl. No.: 13/272,905

(22) Filed: Oct. 13, 2011

Related U.S. Application Data
(63) Continuation-in-part of application No. 12/075,212, filed on Mar. 10, 2008.
Application No. 12/075,212 is a continuation-in-part of application No. 12/319,544, filed on Jan. 8, 2009.
Application No. 12/319,544 is a continuation-in-part of application No. 12/070,793, filed on Feb. 20, 2008.

(51) Int. Cl. G01R 31/36; G06F 19/00

(52) U.S. Cl. 702/63

(57) ABSTRACT

A computer system that installs in the proximity of the vehicle's operator by attaching to the vehicle's wiring harness (e.g., via a power outlet in the vehicle cabin). The device, gathers data relating to the operational state of the vehicle's battery, calculates various health information of the battery from the gathered data, and provides the health and operational state of the battery to the vehicle's operator. To facilitate battery health calculations, the device receives input from a temperature sensor that is remote to the battery, such as a temperature sensor in the device's housing or in the vehicle cabin. The temperature reading can be used to approximate the temperature of the battery. The computer system can also support non-battery related functions, such as navigation, theft deterrence, etc. Algorithms utilizing battery health data over multiple load cycles to determine the health of a battery are also disclosed.

### RELATED APPLICATIONS

This application is a continuation-in-part of U.S. patent application Ser. No. 12/075,212, filed Mar. 10, 2008 by the same inventors, which is incorporated herein by reference in its entirety.

This application is also a continuation-in-part of U.S. patent application Ser. No. 12/319,544, filed Jan. 8, 2009 by the same inventors, which is incorporated herein by reference in its entirety.

This application is also a continuation-in-part of U.S. patent application Ser. No. 12/070,793, filed Feb. 20, 2008 by the same inventors, which is incorporated herein by reference in its entirety.

### BACKGROUND OF THE INVENTION

1. Field of the Invention

The present invention relates to the field of computers. In particular it relates to the gathering and analysis of information that describes the health and operational state of batteries using a computer attached to a vehicle's wiring harness.

2. Prior Art

All batteries fail. In particular the automobile battery is particularly onerous. Automobile manufactures currently provide only the real-time state of the car's charging system (alternator) when the engine is running. The battery is only one component of this system. This system warns the motorist when there is a problem with the charging system by using a dash mounted voltmeter, ammeter or more commonly a warning lamp which is often referred to as the “idiot light”. This information should not be confused nor equated with the operating state or the overall health of the battery, itself. Typically a loose or broken alternator belt causes the warning lamp to come on.

Automobile battery malfunctions are seldom caused by a factory defect; driving habits are the more common culprits. The heavy auxiliary power drawn during a short distance driven never allows the periodic fully saturated charge that is so important for the longevity of a lead acid battery.

A German manufacturer of luxury cars reveals that of every 400 car batteries returned under warranty, 200 are working well and have no problem. Low charge and acid stratification are the most common causes of the apparent failure. The car manufacturer says that the problem is more common on large luxury cars offering power-hungry auxiliary options than on the more basic models.

It would be important to know when the health of a battery has deteriorated sufficiently to signal that a failure is impending. In some situations this information could be life-saving such as when operating in combat zones or under severe weather conditions. It would also be important to know that by merely changing the usage pattern of a vehicle such as combining multiple shopping trips into a single extended trip or by knowing when to apply an external battery charger that the life of the battery would be extended and impending failures avoided.

A system by which the driver of an internal combustion engine automobile, the skipper of a boat, the driver of a hybrid vehicle, or the driver of an electric vehicle can know both the operating state and the general health of their batteries would therefore be desirable.

### BRIEF SUMMARY OF THE INVENTION

Per one embodiment, the present invention uses a single computer system that takes advantage of an existing wiring harness in order to install remotely from the battery and locally to the operator (e.g., within the passenger compartment of the vehicle). The computer system contains facilities for attaching to the battery's power source as delivered through the wiring harness. The computer system has facilities for measuring the battery voltage in the wiring harness, for measuring temperature (in some cases remotely from the battery), and for measuring time. The computer system also includes storage facilities for retaining a history of these measurements. In addition, the computer system contains algorithms for diagnosing the general health of the battery based upon the active and historical measurements. Finally the computer system makes the active state and the health of the battery known to the operator directly through its operator interface.

Per another embodiment, the present invention additionally includes facilities for remotely monitoring the battery's temperature and current. These measurements can be included in the algorithms for diagnosing the general health of the battery based upon active and historical measurements.

This invention is also cognizant of the economy and facilitation achieved by combining the battery monitor function with non-related systems such as automobile sound systems, tire pressure systems, global positioning systems and theft deterrent systems. All of these different systems contain microprocessors which are typically underutilized. In the $257 billion dollar automotive aftermarket, these systems are sold and installed as single function devices with separate enclosures. Also, given the power requirements of today's microprocessor technology it is not feasible to build self-powered devices using an internal power source such as a 9v battery. The installation of these systems therefore becomes problematic in that they typically must be wired into the vehicle's wiring harness in order to utilize the vehicle's primary power source. This usually requires the services of a professional installer or skilled technician. Therefore, in order to economize both manufacturing costs and installation costs the combining of battery monitoring with non-battery related functionality in the same enclosure is therefore deemed desirable.

Accordingly, a computer system of the invention can further include means for performing non-battery related functions such as receiving global positioning information or tire pressure information and making the vehicle operator aware of this information.

According to a particular embodiment, a computer system of the invention installs remotely from the battery, such as near, on, or in the automobile's dash. The computer system contains facilities for attaching to and measuring battery voltage through the vehicle's wiring harness. The computer system also includes a temperature sensor, a means for measuring time and a data storage facility for retaining a history of measurements. The computer system measures the elapsed time since the engine was last turned off and/or started. After an appropriate elapsed time, temperature and battery voltage data are used to determine the state of charge of the battery, the initial voltage drop when the engine is started, and the total time needed to start the engine. These measurements can be used to determine the health of the battery. If the state of charge of the battery is too low, the operator is warned. Additionally, when the initial voltage drop and/or start time become erratic (e.g., exceed certain thresholds as compared to previously-recorded initial voltage drop(s) and/or start time(s)), the operator of the vehicle is notified. These and other battery health information and warnings (e.g., over- and under-charging) can be determined and generated. Advantageously, all information needed to determine the health of the battery is obtained through the vehicle's wiring harness, optionally inside the passenger cabin of the vehicle.

When the temperature sensor is not physically attached to the battery's case, the temperature of the battery can be approximated by using a temperature sensor that is remote from the battery (e.g., a temperature sensor inside the vehicle's cabin). Other algorithms make use of this approximated temperature when calculating battery health information.

According to another embodiment of the invention, the computer system includes an auxiliary power supply (e.g., an electric double layer capacitor) that provides electrical power to the computer system. The auxiliary power supply is useful to power the computer system when it is not receiving power through the wiring harness.

A particular battery monitor of the present invention is adapted to engage a parallel circuit of the wiring harness of the vehicle via a 12-Volt power outlet (e.g., a cigarette lighter outlet, accessory power outlet, etc.) inside the vehicle. The battery monitor contains algorithms to approximate the temperature of the battery and to determine the health of the battery. When any of these algorithms indicates a deteriorating battery, a warning can be provided to the operator via a user interface of the battery monitor (e.g., via a display, warning light(s), warning sound(s), etc.). The battery monitor can be self-contained and include a dedicated temperature sensor and auxiliary power supply within its own housing. The housing of the battery monitor can also include one or more pivoting sections such that the position of the user interface can be easily adjusted for viewing, etc.

A method for monitoring the health of a battery via a wiring harness of a vehicle is also disclosed. The method includes the steps of electrically engaging the wiring harness, measuring a first value of a health parameter of the battery during a first battery loading cycle, storing the first value as part of a history of the health parameter, measuring a second value of the health parameter during a second battery loading cycle, comparing the second value and at least a portion of the history, and generating an alarm if the comparison indicates that the battery might fail. For example, the alarm can be generated if the difference between the second value and the first value is greater than a predetermined differential value. As another example, the alarm can be generated if the difference between the second value and an average of prior values stored in the history is greater than a predetermined value. Temperature measurements can also be measured during the loading cycles and stored in the history, and comparisons between the second value and the history can be made according to temperature.

### BRIEF DESCRIPTION OF THE DRAWINGS

FIG. 1 is a block diagram of a single-function computer system that is dedicated to monitoring the state of the battery, calculating its health and making this information available to the vehicle operator by monitoring the vehicle battery's voltage.

FIG. 2 is a block diagram of a single-function computer system that is dedicated to monitoring the state of the battery, calculating its health and making this information available to the vehicle operator by monitoring the vehicle battery's voltage, current and temperature.

FIG. 2A is a flow chart illustrating the steps taken by the structural illustration of FIG. 2 as it collects battery data, calculates battery health and displays this information.

FIG. 3 is a block diagram of a dual-function computer system that monitors both the vehicle's battery and tire pressure.

FIG. 3A is a flow chart illustrating the steps taken by the structural illustration of FIG. 3 as it monitors tire pressure and the vehicle's battery.

FIG. 4 is a block diagram of a dual-function computer system that monitors the battery and includes a global positioning system.

FIG. 5 is a block diagram of a dual-function computer system that monitors the battery and includes an audio stereo sound system.

FIG. 6 is a block diagram of a dual-function computer system that monitors the battery and includes a theft deterrent system.

FIG. 7 is a block diagram of a dual-function computer system that utilizes a voltage sensor and a temperature sensor that are remote from the battery to monitor the health of the vehicle's battery and to perform a secondary function.

FIG. 8 is a block diagram showing the dual-function computer system of FIG. 7 in greater detail.

FIG. 9A is a flow chart illustrating a Temperature Approximation algorithm used by the system of FIGS. 7 and 8 to approximate the temperature of the vehicle's battery.

FIG. 9B is a flow chart illustrating a Charge-State algorithm used by the system of FIGS. 7 and 8 to calculate the battery's state of charge.

FIG. 9C is a flow chart illustrating a Start-Voltage algorithm used by the system of FIGS. 7 and 8 to determine the initial start voltage of the battery.

FIG. 9D is a flow chart illustrating a Start-Time algorithm used by the system of FIGS. 7 and 8 to determine the engine start time using the battery.

FIG. 10A is a voltage trace taken of a battery during a first engine start cycle.

FIG. 10B is a subsequent voltage trace taken of the same battery during a second engine start cycle under the same conditions as FIG. 10A.

FIG. 10C is a third voltage trace taken of the same battery during a third engine start cycle under the same conditions as FIGS. 10A and 10B.

FIG. 11 is a block diagram of a single-function computer system that employs a remote temperature sensor to monitor the health of the battery.

FIG. 12 is a block diagram showing the single-function computer system of FIG. 10 in greater detail.

FIG. 13 shows a perspective view of a battery monitoring device and a vehicle dashboard.

### DETAILED DESCRIPTION OF THE INVENTION

The following descriptions are provided to enable any person skilled in the art to make and use the invention and are provided in the contexts of the particular embodiments. Various modifications to the embodiments are possible and the generic principles defined herein may be applied to these and other embodiments without departing from the spirit and scope of the invention. Thus the invention is not intended to be limited to the embodiments shown but is to be accorded the widest scope consistent with the principles, features and teachings disclosed herein.

In accordance with one embodiment, the present invention provides a single-function computer system that attaches to a vehicle's wiring harness at a point that is local to the location of the vehicle's operator (e.g., inside the passenger compartment of the vehicle) but remote from the location of the battery.

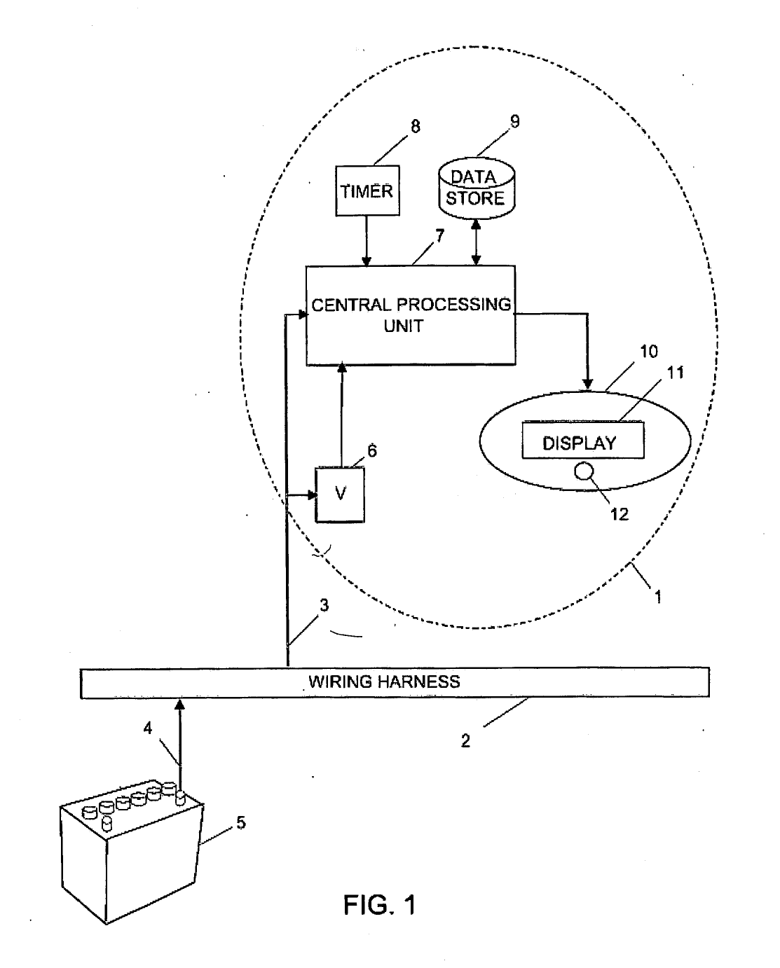

FIG. 1 is a block diagram illustrating a single-function environment. Computer system 1 attaches to the vehicle's wiring harness 2 using wire 3. The wiring harness 2 includes a power wire 4 that is attached to the vehicle's battery 5. Those skilled in the art will realize that wiring harness 2 is only shown representationally. In fact, wiring harness 2 will include a plurality of parallel circuits/lines that supply electrical power to various locations of the vehicle. The wire 3 couples the computer system 1 to one of these parallel circuits and represents a parallel connection the wiring harness.

Power from the wiring harness 2 is used to power computer system 1 from wire 3. The power from the wiring harness 2 is also fed into voltage sensor 6 which allows central processing unit 7 to sample the vehicle's voltage at any instant in time. Central processing unit 7 displays the sample information on display 11 of console 10 when so directed by the console control 12. By means specified in various software algorithms computer system 7 renders a profile of the current health of the battery. These algorithms make use of the history contained in data store 9. This history is made rich by a time profile whose creation by central processing unit 7 is facilitated by timer 8 and included with the voltage samples as saved in data store 9. The time profile permits the means by which the central processing unit 7 can, as an example, estimate driving time in automobiles based upon periodic changes in battery voltage. This in turn relates directly to the health and well being of the battery. Central processing unit 7 displays the battery health information on display 11 of console 10 when so directed by the console control 12. Under those conditions wherein bad battery health is detected, central processing unit 7 overrides console control 12 and causes the bad health information to be shown immediately and unconditionally to the operator on display 11.

In accordance with another embodiment, the present invention provides a single-function computer system that attaches to a vehicle's wiring harness at a point that is local to the location of the vehicle's operator but remote from the location of the battery and includes facilities added local to the vehicle's battery that provide battery current and battery temperature information.

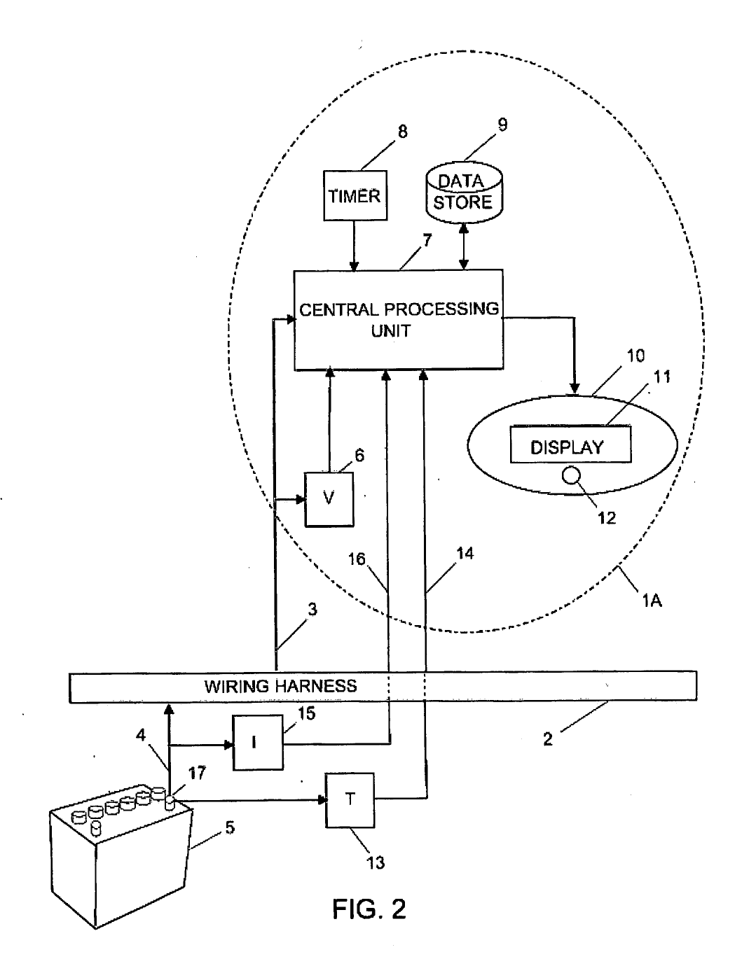

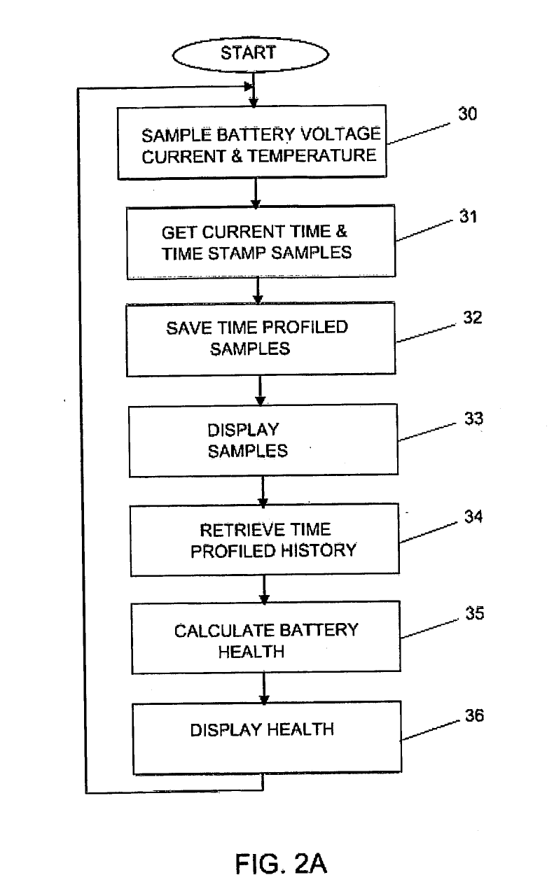

FIG. 2 is a block diagram illustrating a single-function environment. Computer system 1A is similar to computer system 1 (FIG. 1) except it includes an attachment wire 16 to a battery current sensor 15 that is installed on or near the positive terminal 17 of battery 5. It also includes an attachment wire 14 to a battery temperature sensor 13 that is installed on or near battery 5. Central processing unit 7 samples the battery's voltage as provided by voltage sensor 6, the battery's current as provided by current sensor 15 and the battery's temperature as provided by temperature sensor 13. Central processing unit 7 displays the sampled voltage, current and temperature information on display 11 of console 10 when so directed by the console control 12. By means specified in various software algorithms computer system 7 renders a profile of the current health of the battery. These algorithms make use of the history contained in data store 9. This history is made rich by a time profile whose creation by central processing unit 7 is facilitated by timer 8 and included with the voltage, current and temperature samples as saved in data store 9. Central processing unit 7 displays the battery health information on display 11 of console 10 when so directed by the console control 12. Under those conditions wherein bad battery health is detected, central processing unit 7 overrides console control 12 and causes the bad health information to be shown immediately and unconditionally to the operator on display 11.

FIG. 2A is a flowchart illustrating the steps taken by computer system 1A (FIG. 2) in order to gather, analyze and display the current operating state and the rendered health of battery 5 (FIG. 2). In step 30 the current state of the battery is sampled. In step 31 the current time is obtained. In step 32 the current time is added to the battery samples and saved. The current operational state of the battery as defined by the battery samples taken in step 30 are displayed in step 33. In step 34 the history of the time profiled battery samples is made available in step 35 to a library of computer algorithms which provide the means by which the health of the battery is calculated. In step 36 the calculated health of the battery is displayed.

In accordance with yet another embodiment, the present invention provides a dual-function computer system that attaches to a vehicle's wiring harness at a point that is local to the location of the vehicle's operator but remote from the location of the battery and includes facilities added local to the vehicle's battery that provide battery temperature information. In addition to processing battery information this embodiment processes tire pressure information that it is provided by a wireless connection to tire pressure sensors.

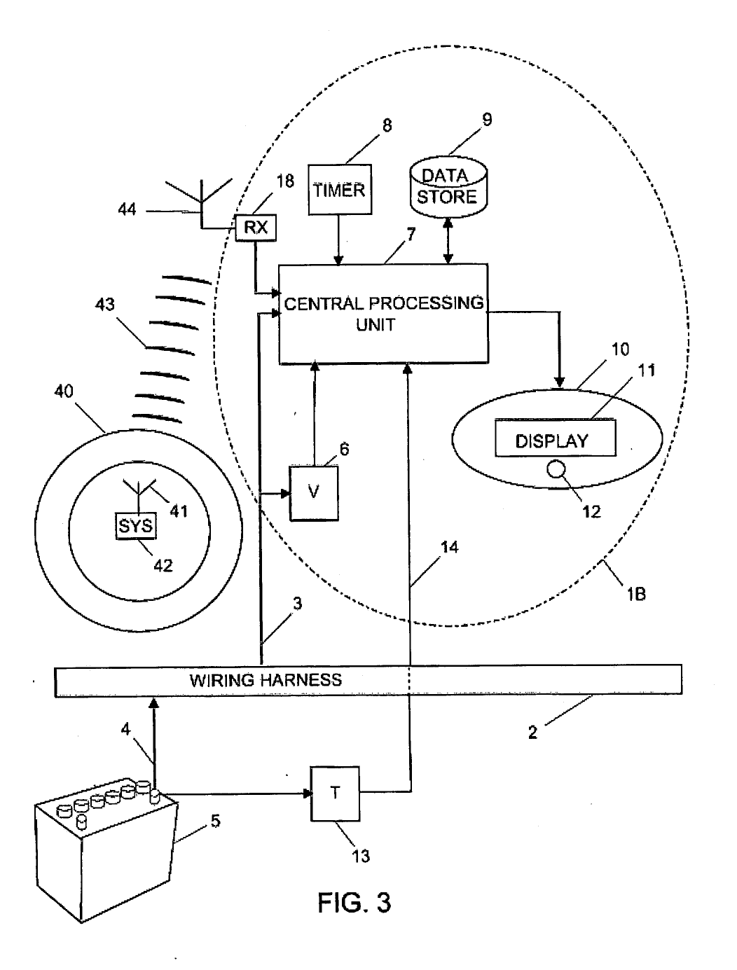

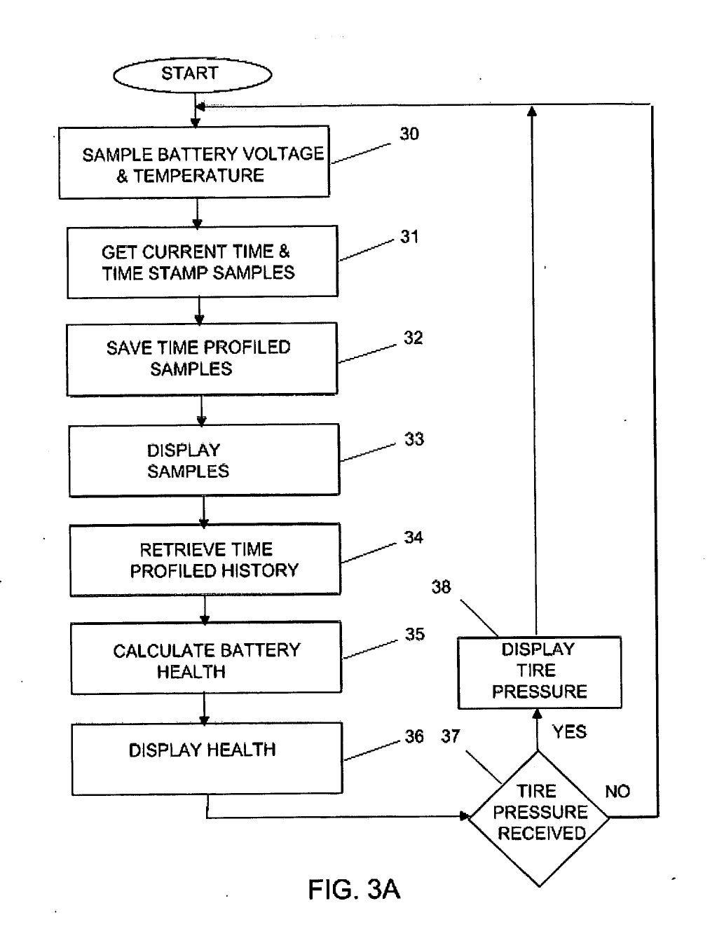

FIG. 3 is a block diagram illustrating a dual-function environment. Computer system 1B is a dual-function computer system. It gathers, analyzes and displays battery information in the same manner as computer system 1A (FIG. 2) except in this embodiment battery current is not sampled. Computer system 1B also receives tire pressure information from computer system 42 mounted inside tire 40. This wireless information 43 is transmitted by computer system 42 using antenna 41. This wireless information 43 is received by antenna 44 and made available to central processing unit 7 by wireless transceiver 18. It is displayed on display 11 of console 10 when so directed by console control 12.

FIG. 3A is a flowchart illustrating the steps taken by computer system 1B (FIG. 3) in order to gather, analyze and display the current operating state along with the rendered health of battery 5 (FIG. 3) and to also collect and display tire pressure information. In step 30 the current state of battery 5 (FIG. 3) is sampled. In step 31 the current time is obtained. In step 32 the current time is added to the battery samples and saved. The current operational state of the battery as defined by the battery samples taken in step 30 are displayed in step 33. In step 34 the history of the time profiled battery samples is made available in step 35 to a library of computer algorithms which provide the means by which the health of the battery is calculated. In step 36 the calculated health of the battery is displayed. Program control is then directed to step 37 where a check is made to see if tire pressure information has been received on the wireless link. If tire pressure information has not been received program control is directed to step 30. If tire pressure information has been received, this information is displayed on the operator's console in step 38. Program control is then directed to step 30.

In accordance with yet another embodiment, the present invention provides a dual-function computer system that attaches to a vehicle's wiring harness at a point that is local to the location of the vehicle's operator but remote from the location of the battery and includes facilities added local to the vehicle's battery that provide battery temperature information. In addition to processing battery information this embodiment processes location, speed, direction and time information that it is provided by a microwave connection to a Global Positioning System satellite.

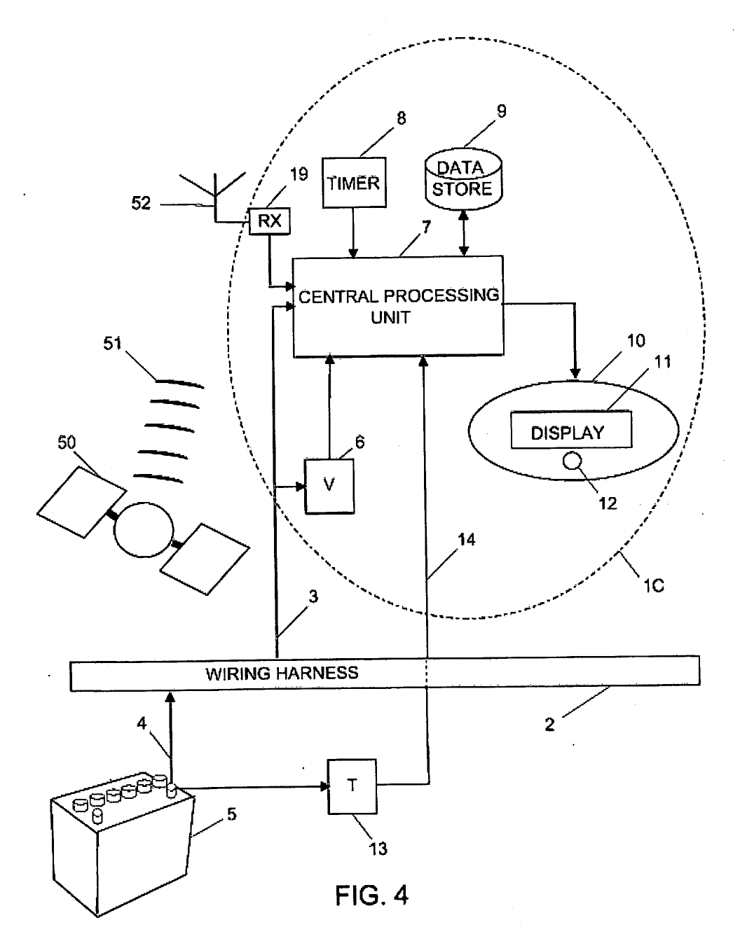

FIG. 4 is a block diagram illustrating a dual-function environment. Computer system 1C is a dual-function computer system. It gathers, analyzes and displays battery information in the same manner as computer system 1B (FIG. 3). Central processing unit 1C also receives location, speed, direction and time information from GPS satellite 50. The microwave transmitted information 51 is received by antenna 52 and made available to central processing unit 7 by microwave transceiver 19. The GPS information is analyzed by central processing unit 7 and then displayed on display 11 of console 10 when so directed by console control 12.

In accordance with still yet another embodiment, the present invention provides a dual-function computer system that attaches to a vehicle's wiring harness at a point that is local to the location of the vehicle's operator but remote from the location of the battery and includes facilities added local to the vehicle's battery that provide battery temperature information. In addition to processing battery information this embodiment includes an audio stereo sound system.

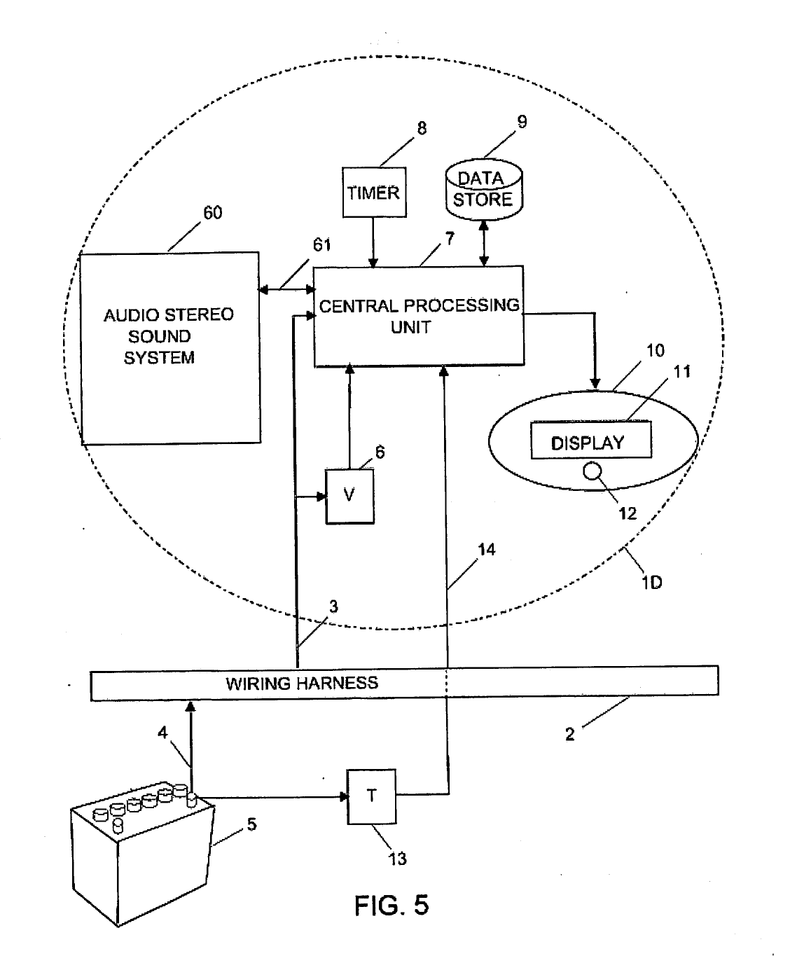

FIG. 5 is a block diagram illustrating a dual-function environment. Computer system 1D is a dual-function computer system. It gathers, analyzes and displays battery information in the same manner as computer system 1B (FIG. 3). Computer system 1D also includes an audio stereo sound system 60 that includes an interface 61 to central processing unit 7 and utilizes console 10 as the means for providing operator control of the audio stereo sound system 60.

In accordance with still yet another embodiment, the present invention provides a dual-function computer system that attaches to a vehicle's wiring harness at a point that is local to the location of the vehicle's operator but remote from the location of the battery and includes facilities added local to the vehicle's battery that provide battery temperature information. In addition to processing battery information this embodiment includes a theft deterrent system.

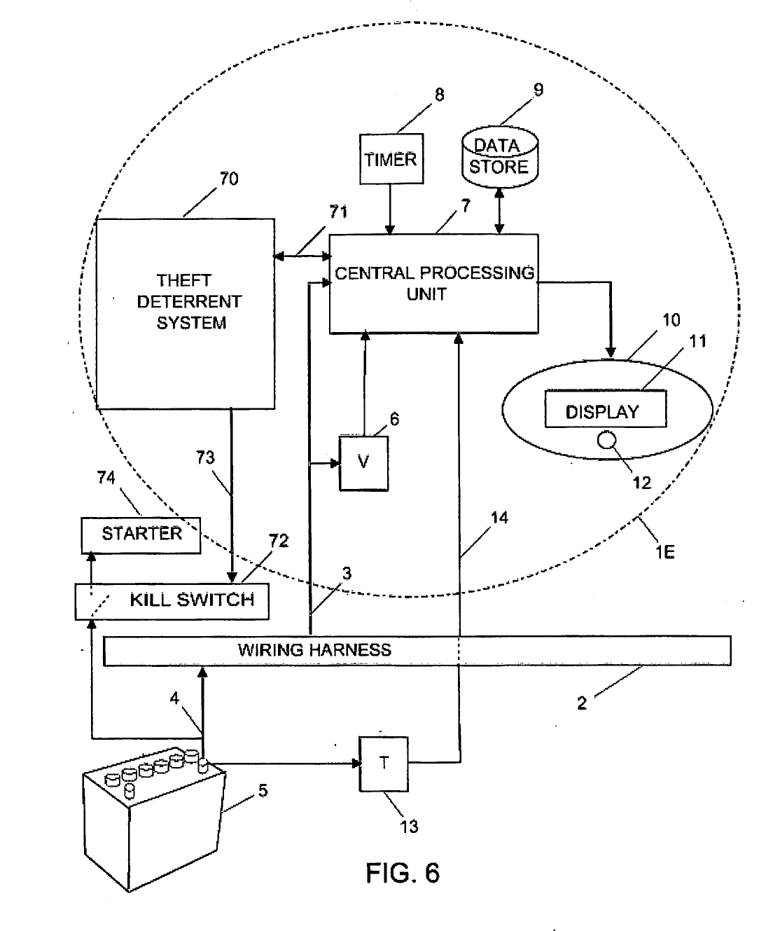

FIG. 6 is a block diagram illustrating a dual-function environment. Computer system 1E is a dual-function computer system. It gathers, analyzes and displays battery information in the same manner as computer system 1B (FIG. 3). Central processing unit 1E also includes a theft deterrent system 70 that includes an interface 71 to central processing unit 7 and utilizes console 10 as the means for providing operator control of the theft deterrent system 70. Included in the theft deterrent system 70 is a vibration sensor (not shown), an audible alarm (not shown) and connection 73 that controls kill switch 72 which in turn can render starter motor 74 inoperable by turning off power wire 4.

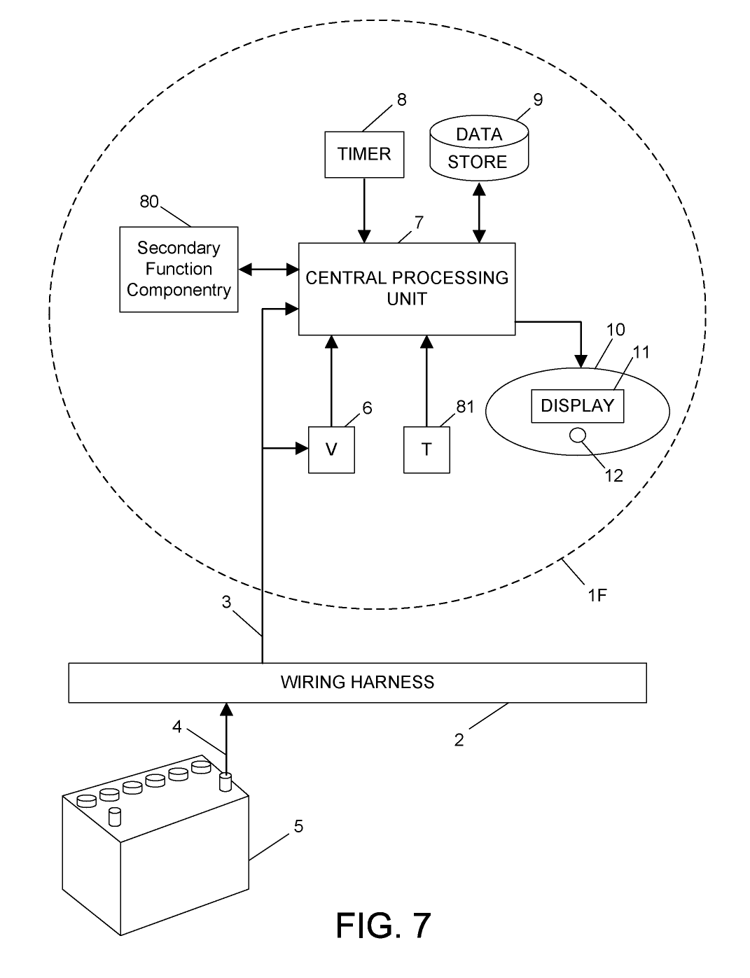

FIG. 7 is a block diagram illustrating yet another dual-function computer system 1F according to the invention that analyzes data pertaining to the vehicle's battery, determines the battery's health, and conveys battery health information to the vehicle's operator. Computer system 1F also provides functionality that is different from battery monitoring and, therefore, includes secondary function componentry 80 (e.g., a secondary system) in communication with the central processing unit 7. Computer system 1F further includes a temperature sensor 81, which is positioned remotely from the vehicle battery 5. In fact, all of computer system 1F can be positioned remotely from the battery 5, such as inside the passenger compartment of the vehicle, on the opposite side of the vehicle's firewall as the battery, etc. Computer system 1F includes like-numbered elements that are similar to those that were previously described herein. Descriptions of the like-numbered elements are, therefore, omitted in the discussion of FIG. 7.

Secondary function componentry 80 represents any portion of a secondary system that provides a function different than battery monitoring. For example, secondary function componentry 80 could be an audio stereo system, a theft deterrent system, a vehicle control computer, etc. Componentry 80 might also include means for intercommunicating with remote devices, such as a tire pressure monitoring transceiver, a GPS receiver, etc. While secondary function componentry 80 is shown with a single interface to central processing unit 7, computer system 1F can include any suitable means for facilitating communication between the secondary function componentry 80 (individually or collectively) and the other elements of computer system 1F.

A particular advantage of computer system 1F is that the temperature sensor 81 does not have to be positioned near the battery 5 for the computer system 1F to effectively monitor the health of the battery 5. Computer system 1F utilizes the remote temperature data to approximate the temperature of the battery 5. The inventors have found that after a vehicle has been turned off for a predetermined amount of time (e.g., four hours or more), the battery temperature can be accurately approximated by the temperature detected by the remote temperature sensor 81. Therefore, the temperature sensor 81 can be, for example, an in-cabin temperature sensor that is also associated with the vehicle's climate control system.

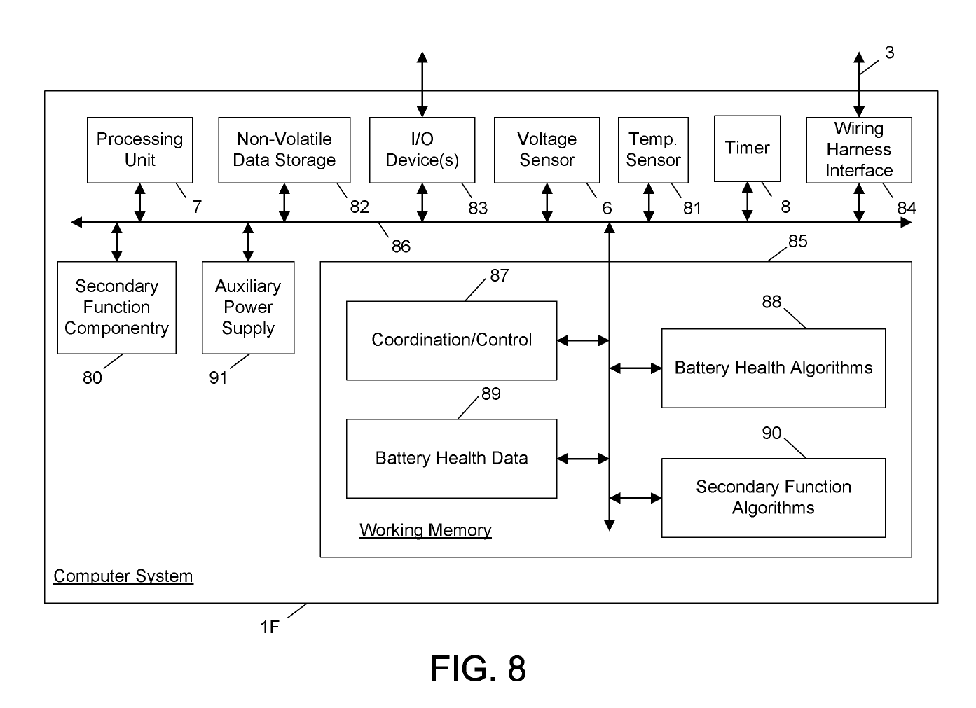

FIG. 8 is a block diagram showing computer system 1F in greater detail. As indicated previously, computer system 1F includes voltage sensor 6, processing unit 7, timer 8, secondary function componentry 80, and temperature sensor 81. In FIG. 8, computer system 1F is also shown to include non-volatile data storage 82, one or more user input/output (I/O) devices 83, a wiring harness interface 84, a working memory 85. All of these components are interconnected via interconnection circuitry 86 such that they can intercommunicate as necessary.

Processing unit 7 executes data and code stored in working memory 85, causing computer system 1F to carry out its battery monitoring and secondary functions (e.g., measuring temperature, determining battery health, navigation, theft deterrence, etc.). Non-volatile data storage 82 provides storage for data (e.g., voltage, temperature, and time profiles) and code (e.g., boot code and algorithms) that are retained even when computer system 1F is powered down. Non-volatile data storage 82 can be, for example, flash memory and/or EEPROM. I/O devices 83 facilitate interaction between a vehicle operator and computer system 1F, and include items such as display 11 and console control 12. I/O devices 83 can also include a speaker that generates audible notifications. Voltage sensor 6 measures the voltage in the vehicle wiring harness 2. Temperature sensor 81 measures the ambient temperature of the environment in which temperature sensor 81 is located. Timer 8 provides time information to facilitate the functions and algorithms of computer system 1F. Wiring harness interface 84 facilitates an electrical connection between computer system 1F and the wiring harness 2 via the wire 3, including providing electrical power to interconnection circuitry 86. Interconnection circuitry 86 (e.g., a system bus, printed circuit board, etc.) facilitates electrical power distribution and intercommunication between the various components of computer system 1F.

Working memory 85 (e.g., random access memory) provides temporary storage for data and executable code, which can be loaded into working memory 85 during both start-up and on-going operation. Working memory 85 includes coordination and control module 87, battery health algorithms 88, battery health data 89, and secondary function algorithms 90.

The modules of working memory 85 provide the following functions. Coordination and control module 87 provides an operating environment for computer system 1F and coordinates and controls the operation of the various processes running in working memory 85. Module 87 can also provide control signals to the other components of computer system 1F as needed. For example, module 87 could start and stop the timer 8, request voltage and/or temperature readings, coordinate processor time between battery monitoring and secondary functions, etc. Battery health algorithms 88 are employed to determine the health of the battery 5 based on the collected battery health data 89. Battery health algorithms 88 may also include look-up tables useful in determining element(s) of the battery's health. Battery health data 89 represents data associated with the battery 5 that is collected by computers system 1F, such as voltages in the wiring harness 2, temperatures detected by sensor 81, time values generated by timer 8, previous analyses generated by the battery health algorithms, etc. Battery health data 89 can also include data associated with multiple engine start/stop cycles. Because the amount of battery health data 89 might be large, portions of battery health data 89 can be written to and read from non-volatile data storage 82 as necessary to reduce the amount residing in working memory 85. Portions of battery health data 89 can also be discarded when no longer needed. Battery health data 89 can also be stored as needed in non-volatile data storage 82 such that it is retained even when computer system 1F is powered down (e.g., when the ignition is off, etc.). Secondary function algorithms 90 contain algorithms that permit computer system 1F to carry out its secondary function(s), such as navigation, tire pressure monitoring, theft deterrence, audio, video, etc. Coordination and control module 87 ensures that the battery health algorithms 88 and the secondary function algorithms 90 are carried out at the appropriate times and can access the resources of computer system 1F as needed.

There will likely be times when electrical power is not being supplied to system 1F from the wiring harness 2 (e.g., when the ignition key is turned off, when the engine is being started, etc.). Therefore, system 1F includes an auxiliary power supply 91 that provides electrical power to the components of system 1F when electrical power is not otherwise being provided. Optionally, auxiliary power is only provided to the battery monitoring components and not the secondary function componentry 80. Auxiliary power is also provided to the components of system 1F via the interconnection circuitry 86. Auxiliary power supply 91 can be implemented using a variety of means, such as with an electric double layer (“super”) capacitor, a rechargeable battery, etc.

Auxiliary power supply 91 provides the advantage that system 1F can provide battery health information and alarms to and receive input from the operator (via I/O devices 83) even when electrical power is not being supplied from the wiring harness 2. Auxiliary power supply 91 also enables system 1F to be instantly ready to record battery health data by reducing or eliminating the initialization time of computer system 1F.

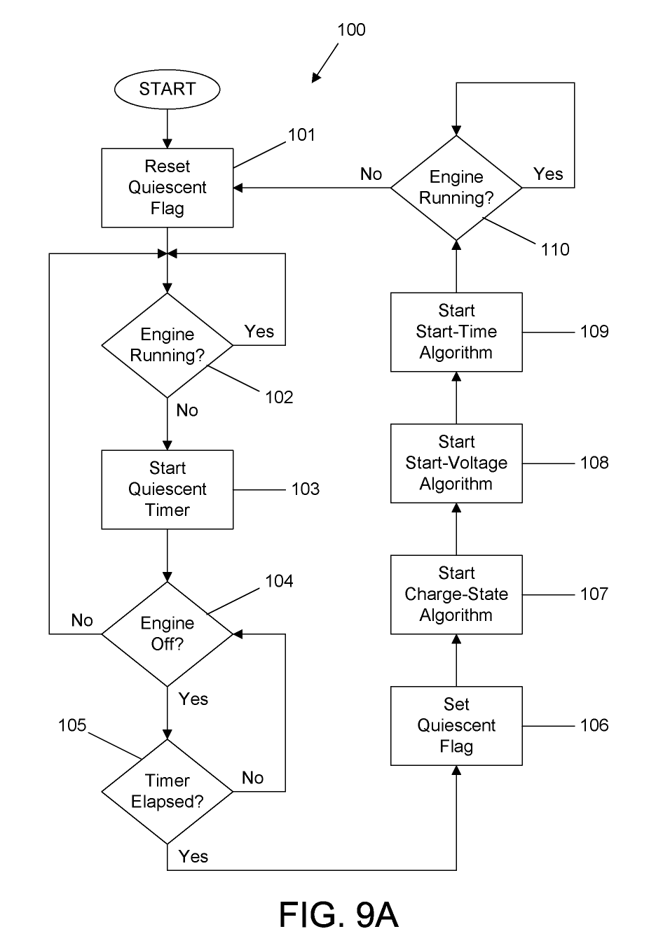

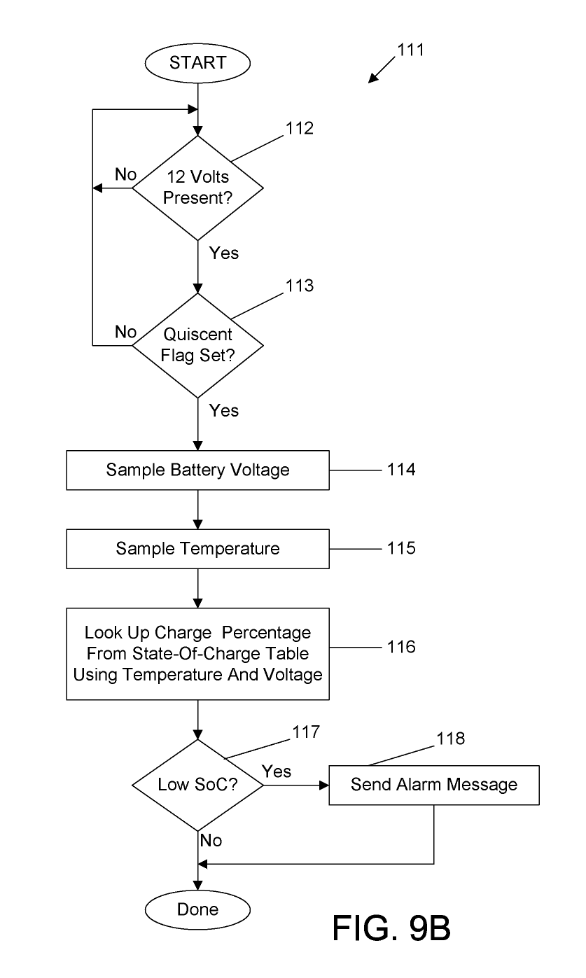

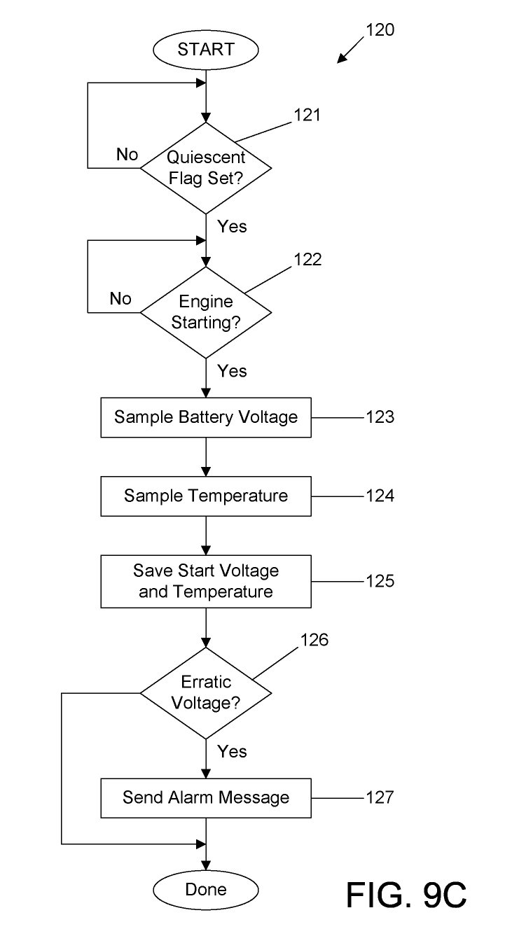

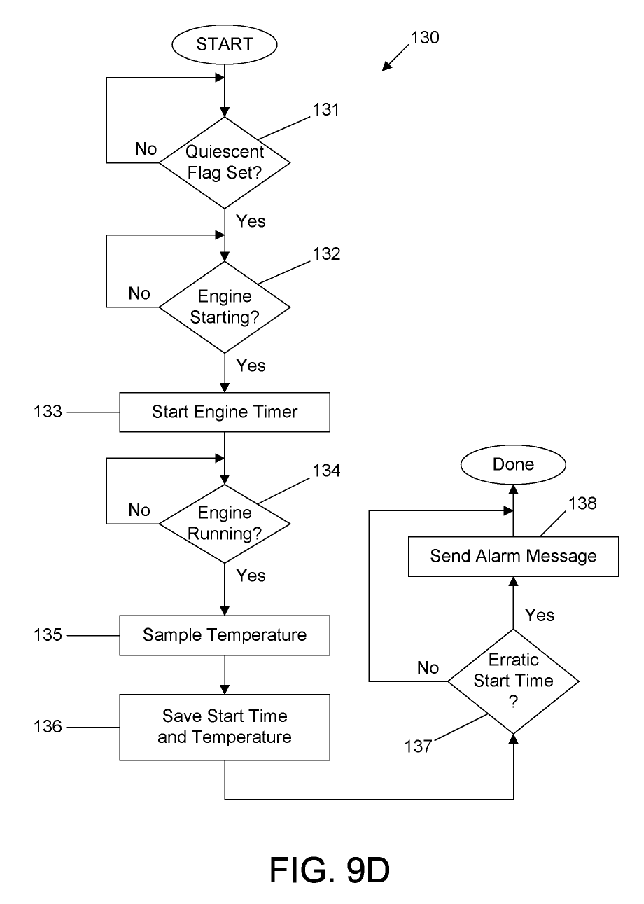

FIGS. 9A-9D are flowcharts summarizing the processes of exemplary battery health algorithms 88 employed by computer system 1F. For the sake of clear explanation, these algorithms are described with reference to particular system elements. However, it should be noted that other elements, whether explicitly described herein or created in view of the present disclosure, could be substituted for those cited without departing from the scope of the present invention. Therefore, it should be understood that the algorithms described herein are not limited to any particular element(s) that perform(s) any particular function(s). Further, some steps of the algorithms need not necessarily occur in the order shown. In some cases two or more steps or steps from different algorithms may occur simultaneously. These and other variations of the algorithms disclosed herein will be readily apparent in view of the present disclosure and are considered to be within the full scope of the invention.

FIG. 9A is a flowchart summarizing an exemplary process performed by a temperature algorithm 100 that, when executed by the computer system 1F, determines if the temperature of the remote starter battery 5 can be approximated. Algorithm 100 is also used to call other battery health algorithms. In step 101 a Quiescent Flag is reset. The Quiescent Flag can be one or more data bits in working memory 85 or non-volatile data storage 82 that, when set, indicate(s) that the engine has been off for a sufficient amount of time that the temperature measured by the remote temperature sensor 81 approximates the temperature of the battery 5. In step 102, if the engine is running, the temperature algorithm does nothing until the engine has stopped. The voltage measured by voltage sensor 6 is used to differentiate engine activity. In step 103, when the engine has stopped, the quiescent time measurement is accomplished by the timer 8. Step 104 also monitors engine activity. If the engine has restarted, program control returns to step 102. However, if the engine is still off, program control proceeds to step 105. Step 105 monitors the quiescent time. If the quiescent time has elapsed, program control goes to step 106, where the Quiescent Flag is set. If not, program control returns to step 104. Program control then proceeds to step 107 causing the Charge State algorithm to execute. Then the method proceeds to step 108 causing the Start-Voltage algorithm to execute. Next, the method proceeds to step 109 causing the Start-Time algorithm to execute. Then, in step 110, a determination is made if the vehicle engine has started and is running. If so, the method waits until the engine is turned off before passing program control back to step 101.

FIG. 9B is a flowchart summarizing an exemplary process performed by a Charge State algorithm 111 (step 107 of FIG. 9A) while executing in computer system 1F. The Charge State algorithm is used to determine the state of charge of the remote starter battery 5 and if the battery 5 is in poor health. In step 112 a check is made to determine if the 12 volts from the starter battery 5 is present. It is possible that this information has been made unavailable by the ignition switch. Program control proceeds to step 113 when 12 volts is present. In step 113, program control proceeds to step 114 when the engine has been off for a predetermined amount of time as made known by the Quiescent Flag. In step 114, the voltage sensor 6 samples the voltage of the starter battery 5. Then, in step 115, the temperature sensor 81 samples the temperature remote from the battery 5. Finally, in step 116, the state of charge of the battery 5 is obtained, for example by utilizing a Temperature Compensated State-of-Charge (SoC) Table based upon the temperature and voltage measurements. SoC tables for batteries are available in the public domain and associated look-up tables can be stored in non-volatile data storage 82 and/or working memory 85 of computer system 1F. The sampled voltage obtained in step 114, the temperature obtained in step 115, and/or the state of charge determined in step 116 can be stored in memory (e.g., working memory 85 and/or non-volatile memory 81) for later retrieval. In step 117, the state of charge is compared with an acceptable state of charge from the SoC table. If the state of charge is below a predetermined threshold, a low state of charge alarm is generated (e.g. on display 11, audibly, etc.) in step 118. The algorithm is now done until the engine again goes into a quiescent state for a predetermined amount of time.

FIG. 9C is a flowchart summarizing an exemplary process performed by a Start-Voltage algorithm 120 (step 108 of FIG. 9A) while executing in computer system 1F. The Start-Voltage algorithm is used to sample the voltage drop of the starter battery 5 while the engine is starting and use this information to determine if the battery 5 is in poor health. In step 121, the process does not advance until the engine has been off for a predetermined amount of time as indicated by the Quiescent Flag. After the engine has been off long enough, the process proceeds to step 122 where the voltage read from voltage sensor 6 is used to detect a start engine condition. When the engine start operation is detected, the process proceeds to step 123 where the large initial voltage drop of the battery 5 is read. (The large initial voltage drop is caused by the surge of power to the engine starter motor.) Then, in step 124 the temperature is read from temperature sensor 81. Next, in step 125, the initial starting voltage read in step 123 and the temperature read in step 124 are saved in memory. For example, the inventors have found it useful to store initial starting voltages in a bin of memory that is indexed by temperature. In step 126, it is determined if the initial starting voltage measured in step 124 is erratic as compared to previous initial start voltage information obtained at the same (or approximately the same) temperature. If so, an alarm is generated in step 127 (e.g., a low start voltage message on display 11, etc.). The algorithm is then done until the engine again goes into a quiescent state for a predetermined amount of time.

There are various ways in which Start-Voltage algorithm 120 can determine that the initial start voltage of battery 5 has become erratic. For example, algorithm 120 could determine that the initial start voltage had become erratic if the magnitude of the voltage change between the initial start voltage measured in step 123 and at least one previous initial start voltage taken at the same (or comparable) temperature was greater than a predetermined voltage differential (e.g., 0.75 V, 1.5V, etc.). As another example, algorithm 120 could determine that the initial start voltage had become erratic if the magnitude of the voltage change between the initial start voltage measured in 123 and the average of a plurality of previous initial start voltages taken at the same (or comparable) temperature was greater than a predetermined differential value. As still another example, algorithm 120 could determine that the initial start voltage had become erratic if the magnitude of the voltage change between the initial start voltage measured in 123 and the lowest initial start voltage of a plurality of previous initial start voltages taken at the same (or comparable) temperature was greater than a predetermined differential value. These and other methods of determining erratic behavior based on initial start voltage are possible. The important aspect of the invention is that the erratic behavior is detected based on actual activity of the battery 5 and not on some information that is universally applied across all batteries. Advantageously, the invention does not require any information as to the battery's age, its size, or the size of the engine.

It should be noted that different predetermined differential values can be employed to produce different alarm sensitivities for erratic behavior, with increasing differentials corresponding to decreasing alarm sensitivity. The inventors have found that more sophisticated vehicle charging systems often require more sensitive alarms, while older vehicles will generate false alarms if the alarm sensitivity is too high.

FIG. 9D is a flowchart summarizing an exemplary process performed by a Start-Time algorithm 130 (step 109 of FIG. 9A) while executing in computer system 1F. The Start-Time algorithm is used to determine the amount of time it takes for the engine to start and to determine if the battery 5 is in poor health. In step 131, the process does not advance until the engine has been off for a predetermined amount of time as indicated by the Quiescent Flag. After the engine has been off for a sufficient amount of time, the process proceeds to step 132 where the voltage read from voltage sensor 6 is used to detect a starting engine condition. When the engine start operation is initially detected, the process proceeds to step 133 where the Engine Start timer is turned on. Timer 8 is used to instantiate this time function. Then, in step 134, the voltage read from voltage sensor 6 is used to determine when the engine has started and is running. When the engine starts running, the process proceeds to step 135 where the temperature is read from temperature sensor 81. At step 136 the engine start time is saved to memory along with the sampled temperature. As before, the start time can be saved in a bin of memory that is indexed by temperature, optionally with other battery health data. Then, at step 137, it is determined if the starting time measured in step 135 has become erratic as compared to previous start time information obtained at the same (or approximately the same) temperature. If so, an alarm is generated in step 138 (e.g., a slow start alarm is displayed). The algorithm is then done until the engine again goes into a quiescent state for a predetermined amount of time.

There are various ways in which Start-Time algorithm 130 could determine that the start time of battery 5 has become erratic. For example, algorithm 130 could determine that the start time had become erratic if the magnitude of the time change between the start time recorded in step 136 and a previous start time taken at the same (or comparable) temperature was greater than a predetermined time differential (e.g., 2.1 seconds, 2.9 seconds, etc.). As before, different time differential values can be employed to produce different alarm sensitivities, with increasing predetermined values corresponding to decreasing alarm sensitivity. As another example, algorithm 130 could determine that the start time had become erratic if the magnitude of the start time change between the start time recorded in step 136 and the average of a plurality of previous start times taken at the same (or comparable) temperature was greater than a predetermined time differential value. As still another example, algorithm 130 could determine that the start time had become erratic if the magnitude of the start time change between the start time recorded in step 136 and either of the longest and shortest start times of a plurality of previous start times taken at the same (or comparable) temperature was greater than a predetermined differential value. Indeed, other methods of determining erratic behavior based on engine start time are possible. However, the important aspect of the invention is that the erratic behavior is detected based actual activity of the battery 5 and not on start time information that is universally applied across all batteries.

The algorithms described in FIGS. 9B-9D indicate that battery health data may be indexed in memory according to temperature. Accordingly, the battery health data may be indexed according to individual temperatures or according to ranges of temperatures. The inventors have found that the health of a battery can be effectively monitored by indexing battery health data according to temperature ranges. Specifically, the inventors have found that the following temperature ranges are satisfactory for car batteries: greater than or equal to 70 degrees Fahrenheit, greater than or equal to 35 but less than 70 degrees Fahrenheit, greater than or equal to 0 but less than 35 degrees Fahrenheit, greater than or equal to minus 10 but less than 0 degrees Fahrenheit, and less than minus 10 degrees Fahrenheit. Other temperature ranges may also be useful.

The algorithms described in FIGS. 9A-9D provide many advantages. For example, by sampling the voltage in the wiring harness 2, the health of the battery 5 can be determined using the charge state of the battery, the engine start time, and/or the initial engine start voltage. Moreover, the invention determines if the battery 5 is behaving erratically by comparing a current engine-start time and/or a current engine-start voltage with a history of engine-start-time information and engine-start-voltage information obtained at the same or comparable temperatures. In other words, the invention provides a battery-specific health analysis that is determined based on previous temperature-dependent measurement(s) of the battery 5 itself. This provides an advantage over prior art battery monitors that utilize predetermined, theoretical, and/or universally-applied threshold values to all batteries. Indeed, all batteries behave differently in different temperatures, and this invention utilizes relative, battery-specific information to determine the battery's health and warn against impending failure.

It is also notable that the algorithms described in FIGS. 9A-9D operate without detecting the current delivered by the battery, for example, via an in-line series connection with the battery. As indicated above, the computer system 1F carries out its battery-monitoring functions using a parallel connection to the battery 5 via the wiring harness 2.

The algorithms described above also have the advantage of monitoring the stress placed upon a battery during actual starting and regular operation as opposed to the steady state load test of the traditional battery load tester. The algorithms of the invention also provide battery information that cannot be obtained with a conventional load tester. For example, calculating the state of charge the battery would otherwise require a technician with a voltmeter, temperature gauge, charge state table and the knowledge as to when a charge capacity measurement can be taken.

While FIGS. 9A-9D describe some particular battery monitoring algorithms in detail, it should be understood that the processes described in FIGS. 9A-9D can be modified or altered without departing from the scope of the invention. For example, the algorithms can include diversions to carry out the secondary function(s) of computer system 1F. Additionally, battery-related information (e.g., visual and audible alarm notifications, voltage measurements, time measurements, etc.) can be supplied to the vehicle operator while the vehicle's engine is running or while the vehicle's engine is off due to the inclusion of auxiliary power source 91. As another example, battery health data collected while the vehicle is running can also be saved to memory. As still another example, each algorithm may have a dedicated quiescent flag such that different algorithms can be executed after different quiescent times. As yet another example, the algorithms might generate alarms according to user-defined alarm thresholds (more sensitive, less sensitive, no alarms, etc.). It will also be apparent that it is possible to measure the voltage in the wiring harness before engine start, during engine start, while the engine is running (the voltage while the alternator is charging), and after the engine is shut off. These voltage measurements can be used by other algorithms to detect conditions such as low battery voltage, alternator over-charging, and alternator under-charging, and to generate alarms as needed. For example, over- and under-charging are indicated by too high and too low of a voltage reading, respectively, while the engine is running. A low voltage warning can be generated if the battery voltage is well below its specified voltage when the engine is off or when it is running. As indicated above, alarms can be generated and conveyed to the operator as needed to indicate particular battery conditions, and specific information associated with these alarms (e.g., type of alarm, voltage, time, etc.) can be displayed to the vehicle operator at any time.

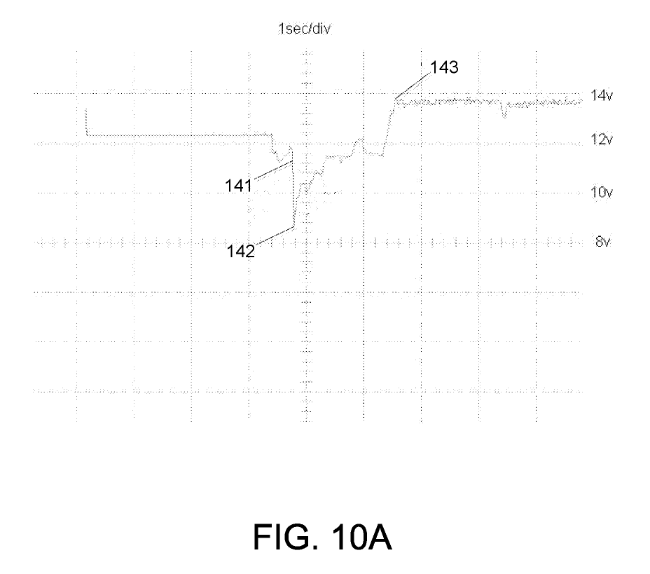

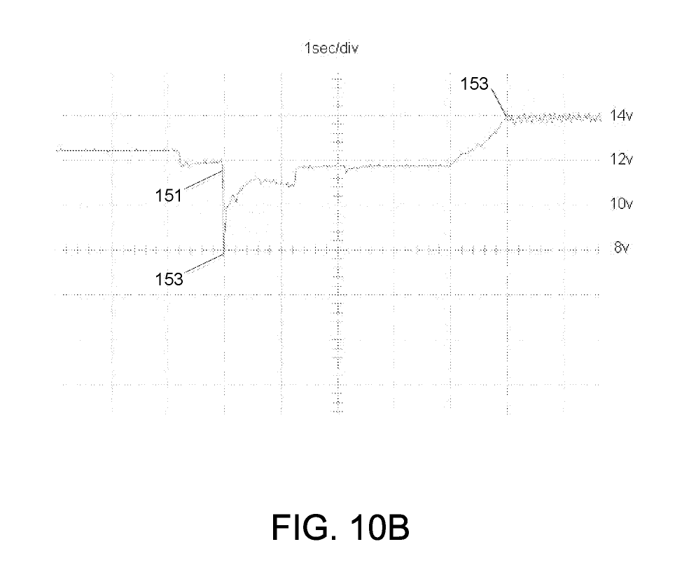

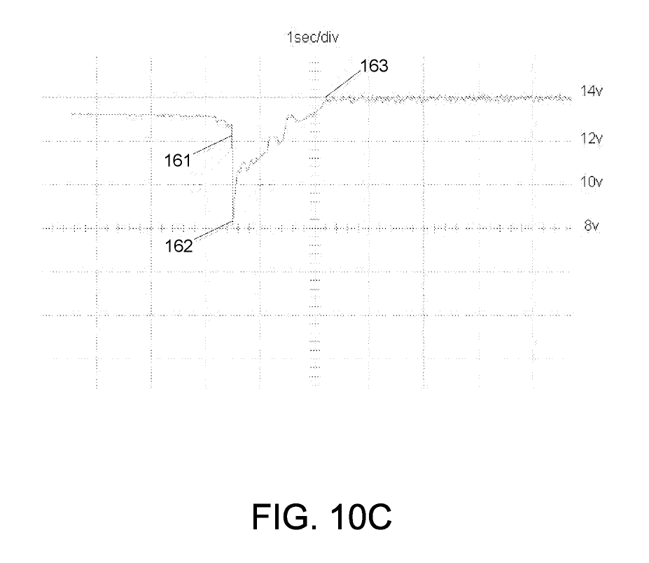

FIGS. 10A-10C show voltage verses time diagrams for three engine start cycles using battery 5 at the same (or comparable) temperature. This voltage information is used by Start-Voltage algorithm 120 (step 126) and Start-Time algorithm 130 (step 137) to determine whether the behavior of battery 5 has become erratic. As described above, the algorithms of this invention have the distinct advantage of being cognizant of the erratic behavior demonstrated by a battery near the end of its life.

FIG. 10A is a start cycle captured at a time when the battery 5 was nearing the end of its life. Reference 141 shows the point where the starter motor was engaged. Reference 142 is the point in the start cycle where the maximum load was manifested. Reference 143 is the point where the engine has started and the alternator is producing power. The maximum load on the battery, as marked by reference 142, resulted in an initial start voltage of 8.5 volts. The time to start the engine, as shown by the elapsed time between references 141 and 143, was 2 seconds.

FIG. 10B is a second start cycle using battery 5 made in the same vehicle at the same (or comparable) temperature as in FIG. 10A. Reference 151 indicates when the starter motor was engaged. Reference 152 indicates where the lowest initial start voltage (maximum load) occurred. During this start, the initial start voltage dropped to 7.7 volts, which is significantly below the previous initial start voltage of 8.5 volts in FIG. 10A. Reference 153 indicates when the engine started. In this case, engine start time between references 151 and 153, was 4.5 seconds, which is more than twice the start time in FIG. 10A.

FIG. 10C is a third start cycle made using the battery 5 in the same vehicle and at the same (or comparable) temperature as in FIGS. 10A and 10B. In FIG. 10C, the starter motor engaged at reference 161, and the maximum drop in initial start voltage is shown at reference 162. In this case, the start voltage dropped to 8.2 volts. The engine started at reference 163, and the engine start time that elapsed between references 161 and 163, was 1.5 seconds.

FIG. 10B indicates that both the initial start voltage and the start time are erratic as compared to the initial start voltage and start time of FIG. 10A. In particular, the change in initial start voltage between FIGS. 10B and 10A is 0.8 volts (|7.7V-8.5V|). Accordingly, Start-Voltage algorithm 120 would generate an alarm based on this erratic behavior of the battery 5, assuming that a differential initial start voltage of 0.75V would indicate erratic behavior. The change in start time between FIGS. 10B and 10A is 2.5 seconds (|4.5 s-2.0 s|). Accordingly, Start-Time algorithm 130 would generate an alarm based on this erratic behavior of the battery 5, assuming a differential start time of 2.1 seconds would indicate erratic behavior.

FIG. 10C also indicates that the start time is erratic compared to the start time of FIG. 10B. The change in start time between FIGS. 10C and 10B is 3.0 seconds (|1.5 s-4.5 s|). Accordingly, Start-Time algorithm 130 would generate an alarm based on this erratic behavior of the battery 5. This slow start alarm would be generated even if a 2.9 second differential start time (less sensitive alarm) was used to indicate erratic behavior. The start cycle of FIG. 10C would not generate a low start voltage alarm unless the difference in starting voltages between FIGS. 10C and 10B was greater than the predetermined voltage differential indicative of an alarm state. If that predetermined differential was 0.75V as above, then no alarm would be generated in this example. This would be inconsequential, however, because the slow start alarm would be generated and would indicate that the battery 5 was in poor health.

FIG. 10C also illustrates that the Start-Voltage algorithm 120 the Start-Time algorithm 130 are complementary to one another. When each is employed, two layers of protection are provided to detect a battery behaving erratically. Additionally, if the Start-Voltage algorithm 120 is unavailable, for example, because power to the passenger cabin is disconnected while the starter motor is engaged, the Start-Time algorithm 130 can still provide protection. For example, the Start-Time algorithm 130 can utilize the time the power to the passenger cabin was disconnected to measure engine start time and to provide slow start warnings accordingly.

In the case of FIG. 10, the battery's behavior was determined to be erratic by comparing the battery health data obtained from the instant start cycle to the battery health data obtained during the immediately preceding start cycle. However, as described above, other methods of determining whether battery health data is erratic is also possible.

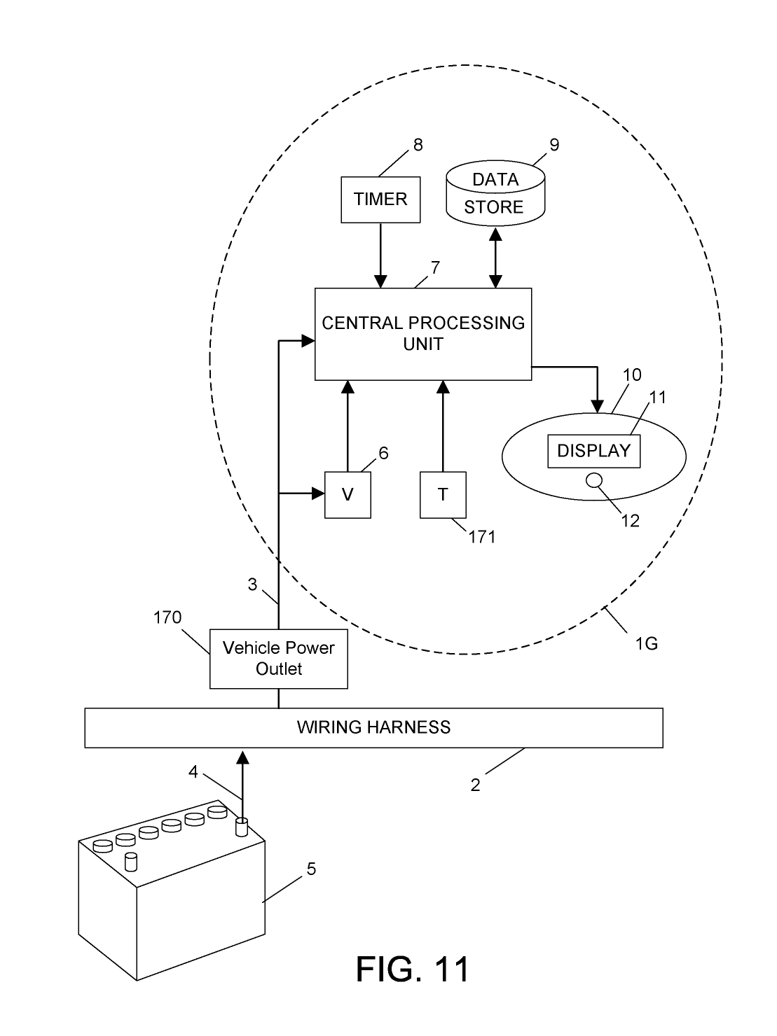

FIG. 11 is a block diagram illustrating a single-function computer system 1G according to another embodiment of the present invention. Computer system 1G is similar to computer system 1F (FIG. 7) except that computer system 1G only performs battery monitoring and is adapted to electrically couple to the wiring harness 2 via a vehicle power outlet 170. The power outlet 170 can be, for example, a 12-volt power outlet for electronic accessories, a cigarette lighter receptacle, etc. Computer system 1G is configured to sample the voltage of the battery 5 via the vehicle power outlet 170 using the voltage sensor 6. Like computer system 1F, computer system 1G also includes a temperature sensor 171 located remotely from the battery 5. In this case, however, temperature sensor 171 is dedicated to (i.e., housed within the same housing as) the computer system 1G.

The computer system 1G provides the advantage that it can be configured to be quickly and selectively disconnected from the wiring harness 2 by removing it from the power outlet 170. In such a case, the console 10 can represent the device's main housing or the like, rather than a vehicle console.

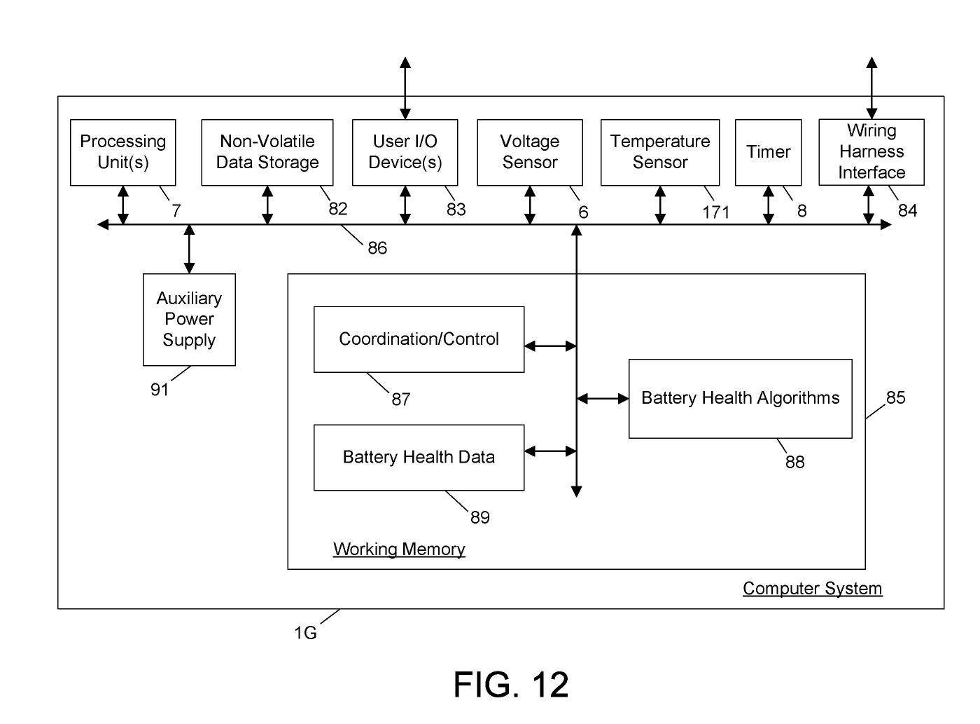

FIG. 12 is a block diagram showing the computer system 1G in greater detail. Many of the components of computer system 1G that are shown in FIG. 12 are similar to like-numbered components of computer system 1F (FIG. 8) and, therefore, will not be described in detail to avoid repetition. However, unlike system 1F shown in FIG. 8, computer system 1G does not include algorithms pertaining to a secondary function, because battery monitoring is its dedicated function. Additionally, the wiring harness interface 84 of system 1G is adapted to selectively interface with a vehicle power outlet 170 instead of, for example, a wiring harness connector or a fuse panel. Battery health algorithms 88, as well as the acquisition, analysis, and displaying of battery health information (e.g., alarms, etc.), are substantially the same as that described with respect to computer system 1F in FIGS. 7-10C.

Regarding auxiliary power supply 91, the inventors have found that an electric double layer (“super”) capacitor, such as a Panasonic™ Stacked Coin Type Series NF capacitor, is especially well-suited to function as an auxiliary power supply 91. This type of capacitor is less expensive and more reliable than a battery. Additionally, implementing such a capacitor within a housing enclosure is often easier because, unlike a battery, access to the capacitor does not have to be provided for replacement purposes.

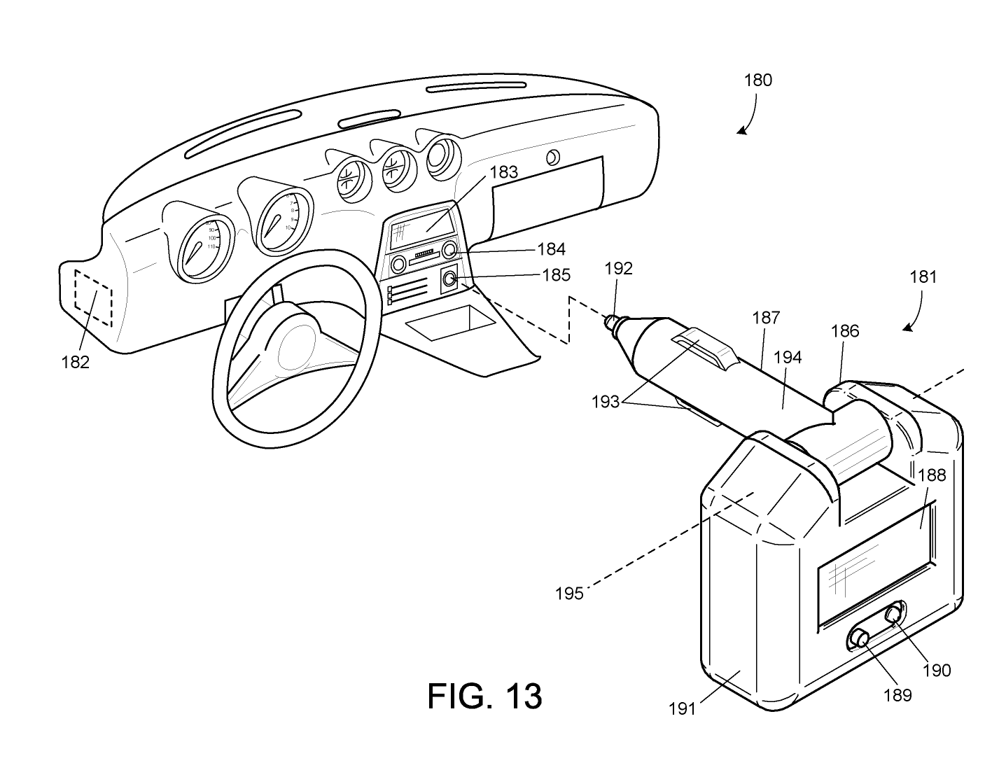

FIG. 13 shows a perspective view of a vehicle dashboard 180 and a battery monitoring device 181 portraying various embodiments of the present invention.

Dashboard 180 includes an electronic control unit (ECU) 182, a navigation system 183, an audio stereo system 184, and a power outlet 185. Like outlet 170, power outlet 185 is a common vehicle power receptacle (e.g., an accessory receptacle, cigarette lighter receptacle, etc.) that facilitates a parallel electrical connection to a parallel circuit of the vehicle's wiring harness 2.

ECU 182 depicts one example of computer system 1F of FIGS. 7-8. Accordingly, ECU 182 is a dual-function computer system that monitors battery health and provides a secondary vehicle function such as traction control, anti-lock braking, etc.

Computer system 1F can also be incorporated into a component of the vehicle's center stack. For example, navigation system 183 can be a dual-function computer system 1F that both monitors battery health and performs navigation functions. Audio stereo system 184 depicts yet another example of computer system 1F of FIG. 7. Audio stereo system 184 can be a dual-function computer system 1F that monitors battery health and facilitates the operation and control of the vehicle's sound system.

Battery monitoring device 181 depicts a particular embodiment of computer system 1G, which is adapted to monitor battery health by plugging into the power outlet 185. Device 181 includes a main assembly 186 pivotally coupled to a plug assembly 187. Main assembly 186 includes the componentry of system 1G (FIG. 12), a display 188, a user input button 189, an indicator light 190 (e.g., a light emitting diode), and a sound indicator (not shown), all housed within a main housing 191. Display 188 is, for example, a liquid crystal display that outputs battery-related information to the user. This battery-related information can include, for example, an alarm indicator including the type of alarm including those types discussed above; voltage, time, and/or state-of-charge values associated with a particular alarm; voltage when the engine is off; charging voltage when the engine is running (battery plus alternator); engine start voltage; engine start time; state of charge of the battery; etc. User input button 189 provides user control for the various functions of the device 181 such as, for example, switching from one mode to another, selecting the battery-related information that should be displayed, selecting the particular vehicle to be monitored, inputting settings, resetting alarm events, etc. Light 190 and sound system provide a means for notifying the user that a condition exists. For example, light 190 can flash or a sound system can be generated to indicate an alarm or when device 181 acknowledges user input (e.g., via button 189). Housing 191 supports and protects the various components of main assembly 186.

Plug assembly 187 includes a center terminal 192, a set of outer terminals 193, and internal wiring (not shown) all housed by a plug housing 194. Center terminal 192 and outer terminals 193 are adapted to electrically contact the positive and negative terminals, respectively, of power outlet 185. The internal wiring is routed through plug housing 194 and into main housing 191 so as to electrically connect terminals 192 and 193 to the computer circuitry located in main housing 191.

Battery monitor device 181 operates locally to the operator of the vehicle and can, therefore, receive user inputs from and/or provide user outputs to the driver of the vehicle while the vehicle is being operated. Plug assembly 187 pivots about an axis 195 such that the angle between plug assembly 187 and main assembly 186 can be adjusted according to user preferences and/or to accommodate for varying power outlet locations. Additionally, because the plug housing 164 can rotate in power outlet 185, the position of main housing 191 is further adjustable. Device 181 can operate and be controlled by the driver at any time, including when the engine is off, when the engine is being started, and after the engine is running.

Device 181 provides the advantages of computer system 1G in a small, self-contained package that can be connected to a vehicle via one of the vehicle's cabin power outlets. As such, the device utilizes algorithms (e.g., FIGS. 9A-10C) to monitor the vehicle's battery health. Device 181 can also be easily moved between different vehicles, and thus monitor different batteries. In such a case, device 181 may include means for differentiating battery health data associated with different vehicles (e.g., different family vehicles, different fleet vehicles of a business, etc.) and means (e.g., button 189) for the user to select between different vehicles. Finally, while the device 181 is shown engaging the power outlet of an automobile, the device 181 can be used with any type of device with a battery that encounters a recurring load on the battery (e.g., a golf cart, a forklift, a boat, etc.). However, depending on the vehicle, some of the alarms may not be available.

The description of particular embodiments of the present invention is now complete. Many of the described features may be substituted, altered or omitted without departing from the scope of the invention. For example, alternate user interfaces (e.g., e.g., keypads, touch screens, etc.), may be substituted for the button and display that are shown. As another example, multiple remote temperature sensors may be used in the invention to approximate the temperature of the battery. These and other deviations from the particular embodiments shown will be apparent to those skilled in the art, particularly in view of the foregoing disclosure.

What is claimed is:

1. A battery monitoring system for electrically engaging a wiring harness of a vehicle, said wiring harness electrically coupled to a terminal of said battery via a power supply line and including a plurality of parallel circuits for supplying electrical power to locations of said vehicle, said battery monitoring system comprising:
a connector adapted to electrically engage a parallel circuit of said wiring harness;
a sensor set operative to generate sensor data indicative of at least one operational characteristic of said battery, said sensor set including a temperature sensor configured to detect an ambient temperature at a location remote from said battery, said sensor data including data indicative of said ambient temperature; and
a processing unit coupled to receive said sensor data from said sensor set and operative to analyze said sensor data to generate battery health information indicative of a condition of said battery.

2. The battery monitoring system of claim 1, further comprising:
memory operative to provide storage for said sensor data; and
a timer coupled to said processing unit and operative to provide time data; and
wherein said processing unit is operative to associate said time data with said sensor data by storing said time data and said sensor data in said memory and to use said associated time data to generate said battery health data.

3. The battery monitoring system of claim 1, further comprising:
a timer coupled to said processing unit and operative to provide time data; and wherein
said battery health information is generated only after a predetermined amount of time has elapsed such that said ambient temperature detected by said temperature sensor approximates a temperature of said battery.

4. The battery monitoring system of claim 3, wherein:
said temperature sensor is located inside a passenger compartment of said vehicle; and
said battery is located outside said passenger compartment of said vehicle.

5. The battery monitoring system of claim 3, wherein said predetermined amount of time is at least four hours.

6. The battery monitoring system of claim 1, wherein said sensor set further includes a voltage sensor electrically coupled to said connector.

7. The battery monitoring system of claim 1, further comprising a housing enclosing at least a portion of said sensor set and said processing unit.

8. The battery monitoring system of claim 7, wherein:
said connector is disposed in a first portion of said housing; and
said processing unit is disposed in a second portion of said housing.

9. The battery monitoring system of claim 8, wherein said first portion of said housing is adjustably mounted to said second portion of said housing.

10. The battery monitoring system of claim 9, wherein said second portion of said housing includes a user interface.

11. The battery monitoring system of claim 8, wherein said first portion of said housing is shaped to permit said connector to engage a power outlet within a passenger compartment of said vehicle.

12. The battery monitoring system of claim 1, wherein at least said processing unit is included in a secondary system having functionality different than battery monitoring.

13. The battery monitoring system of claim 12, wherein said secondary system is a theft deterrent system.

14. The battery monitoring system of claim 12, wherein said secondary system is a climate control system.

15. The battery monitoring system of claim 1, wherein said connector is adapted to engage said wiring harness inside a passenger compartment of said vehicle.

16. The battery monitoring system of claim 1, further comprising an operator interface accessible to an operator of said vehicle, said operator interface operative to receive information based on said battery health data from said processing unit and to provide said information to said operator.

17. The battery monitoring system of claim 1, wherein said battery health information includes the state of charge of said battery.

18. The battery monitoring system of claim 1, wherein:
said sensor set includes a voltage sensor electrically coupled to said connector; and
said battery health information includes the initial voltage drop at said connector when an engine of said vehicle is started.

19. The battery monitoring system of claim 1, further comprising:
a timer operative to provide time data; and wherein
said sensor set includes a voltage sensor electrically coupled to said connector; and
said battery health information includes a start time for an engine of said vehicle.

20. The battery monitoring system of claim 1, further comprising a power supply operative to provide electrical power to at least one of said sensor set and said processing unit when electrical power cannot be received via said connector.

21. The battery monitoring system of claim 20, wherein said power supply includes an electric double layer capacitor.

22. A battery monitoring system for electrically engaging a wiring harness of a vehicle, said wiring harness being electrically coupled to a terminal of said battery via a power supply line and including a plurality of parallel power lines for supplying electrical power to respective circuits of said vehicle, said battery monitoring system comprising:
means for electrically engaging a parallel power line of said wiring harness;
a sensor set operative to generate sensor data indicative of at least one operational characteristic of said battery, said sensor set including means for detecting an ambient temperature at a location remote from said battery, said sensor data including data indicative of said ambient temperature; and
a processing unit coupled to receive said sensor data from said sensor set and operative to analyze said sensor data to generate battery health information indicative of a condition of said battery.

23. The battery monitoring system of claim 22, wherein:
said means for detecting said ambient temperature is configured to detect said ambient temperature inside a passenger cabin of said vehicle; and
said battery is located outside of said passenger.

24. The battery monitoring system of claim 22, wherein at least said processing unit is included in a secondary system having functionality different than battery monitoring.

25. The battery monitoring system of claim 22, further comprising means for providing electrical power to at least one of said sensor set and said processing unit when electrical power cannot be received via said connector.

26. A method for monitoring the health of a battery via a wiring harness of a vehicle, said method comprising:
electrically engaging said wiring harness;
measuring a first value of a health parameter of said battery during a first battery loading cycle;
storing said first value as part of a history of said health parameter;
measuring a second value of said health parameter during a second battery loading cycle;
comparing said second value and at least a portion of said history of said health parameter; and
generating an alarm if said step of comparing said second value and said history of said health parameter indicates that said battery might fail.

27. The method of claim 26, wherein:
said first battery loading cycle and said second battery loading cycle are consecutive loading cycles; and
said step of comparing said second value and said history includes comparing said second value and said first value.

28. The method of claim 27, wherein said step of generating an alarm includes generating an alarm if the difference between said second value and said first value is greater than a predetermined threshold value.

29. The method of claim 26, wherein said step of comparing said second value and said history includes comparing said second value and a plurality of previously-measured values of said health parameter stored as part of said history, said plurality of previously-measured values including said first value.

30. The method of claim 29, wherein said step of comparing said second value with said plurality of previously-measured values includes comparing said second value with the average of said plurality of previously-measured values.

31. The method of claim 30, wherein said step of generating an alarm includes generating an alarm if the difference between said second value and said average is greater than a predetermined threshold value.

32. The method of claim 26, wherein said health parameter includes a voltage present in said wiring harness.

33. The method of claim 26, wherein said health parameter includes a time associated with a battery loading cycle.

34. The method of claim 26, further comprising:
measuring a temperature during said second loading cycle; and wherein
said history is indexed according to temperature; and
said step of comparing said second value and said history includes comparing said second value with portions of said history associated with said temperature.
